(19) United States
(12) Patent Application Publication
(10) Pub. No.: US 2008/0198951 A1
(43) Pub. Date: Aug. 21, 2008

(54) DATA DEMODULATION METHOD AND APPARATUS

(75) Inventor: Myung-sik KIM, Suwon-si (KR)

Correspondence Address: STEIN, MCEWEN & BUI, LLP, 1400 EYE STREET, NW, SUITE 300, WASHINGTON, DC, 20005, US

(73) Assignee: Samsung Electronics Co., Ltd., Suwon-si (KR)

(21) Appl. No.: 11/872,123

(22) Filed: Oct. 15, 2007

(30) Foreign Application Priority Data
Feb. 21, 2007 (KR) 2007-17535

(51) Int. Cl. H04L 27/06; H03M 13/00

(52) U.S. Cl. 375/340; 714/776

(57) ABSTRACT

A data demodulation method and apparatus to prevent a decrease in a data demodulation rate. The data demodulation method includes detecting a frame sync signal from input data, arranging the input data on a predetermined unit basis based on a detected position of the frame sync signal, obtaining N pieces of predetermined unit data with respect to the predetermined unit data by shifting the predetermined unit data by a predetermined unit amount, demodulating the N pieces of predetermined unit data using a demodulation table, and selecting and outputting one of the N pieces of demodulated data as demodulated data of the predetermined unit data.

### CROSS-REFERENCE TO RELATED PATENT APPLICATION

This application claims the benefit of Korean Patent Application No. 2007-17535, filed Feb. 21, 2007 in the Korean Intellectual Property Office, the disclosure of which is incorporated herein in its entirety by reference.

### BACKGROUND OF THE INVENTION

1. Field of the Invention

An aspect of the present invention relates to a data demodulation method and apparatus, and, more particularly, to a method and apparatus to demodulate data based on a frame sync signal.

2. Description of the Related Art

According to conventional methods of demodulating data based on a frame sync signal, when modulated data is input, a frame sync signal is detected, input data is stored on a byte-by-byte basis based on a position of the detected frame sync signal, the stored data is input to a demodulation table, and demodulated data corresponding to the input data is output from the demodulation table.

For example, in a Compact Disc (CD), a frame is composed of 588T as illustrated in FIG. 1, in which a frame sync signal duration is 24T from a first part of the frame. Here, when a device to record or reproduce data to or from a CD reproduces data from the CD, the device detects a frame sync signal corresponding to 24T from the reproduced data, stores data of a symbol unit (14 bits) based on the position where the frame sync signal is detected, and demodulates the stored data using a prepared demodulation table.

However, a frame sync signal may be detected in an incorrect position due to various errors, such as damage to a surface of the CD, an error generated when the CD was manufactured, an error generated when data was recorded on the CD, and an error due to noise contained in a channel when data is reproduced from the CD. The problem of detecting a frame sync signal in an incorrect position may also occur in other optical recording media, such as Digital Versatile Discs (DVDs), High Definition (HD)-DVDs, and Blueray Discs (BDs). In addition, a channel device or a channel decoder receiving data on a frame-by-frame basis may detect a frame sync signal in an incorrect position due to various reasons related to the channel device or the channel decoder.

As described above, if a frame sync signal is detected in an incorrect position when data is demodulated, incorrect data is input to a demodulation table. Thus, incorrect demodulation data is output from the demodulation table. This results in an error in a relevant frame.

For example, in a DVD, a frame may be composed of a frame sync signal duration, duration S #0, and 90 symbol data durations S #1 to S #90 as illustrated in FIG. 2A. Since, as shown in FIG. 2B, a frame of the DVD is composed of 1488T, of which 32T corresponds to the frame sync signal duration, each symbol data duration illustrated in FIG. 2A is composed of 16 bits.

If it is assumed that a frame sync signal of a frame is that illustrated in FIG. 3A, when the frame sync signal is detected in a 1 bit lagging position, as illustrated in FIG. 3B, or a 1 bit leading position, as illustrated in FIG. 3C, stored symbol data such as that of FIG. 3B or FIG. 3C is different from the symbol data illustrated in FIG. 3A.

Thus, incorrect data is input to a demodulation table, and incorrect demodulated data is output from the demodulation table. Therefore, a demodulation error of input data is generated. This results in degradation of reproduction quality. In particular, if demodulation is abnormally performed in an optical media recording and reproducing apparatus, a symbol error rate increases in an Error Correction Code (ECC) decoding process performed after the performance of an ECC demodulation. This results in a decrease in error correction capability.

### SUMMARY OF THE INVENTION

An aspect of the present invention provides a data demodulation method and apparatus for preventing a decrease in a data demodulation rate due to detection of a frame sync signal in a wrong position when data is demodulated based on a detected position of the frame sync signal.

According to an aspect of the present invention, there is provided a data demodulation method comprising: detecting a frame sync signal from input data; arranging the input data on a predetermined unit basis based on a detected position of the frame sync signal; obtaining N pieces of predetermined unit data with respect to the predetermined unit data by shifting the predetermined unit data by a predetermined unit amount; demodulating the N pieces of predetermined unit data using a demodulation table; and selecting and outputting one of the N pieces of demodulated data as demodulated data of the predetermined unit data.

The selecting and outputting may comprise: calculating a hit rate of the demodulation table on a predetermined duration basis for each of the N pieces of demodulated data; determining priorities of the N pieces of demodulated data based on the hit rate of the demodulation table calculated for each of the N pieces of demodulated data on the predetermined duration basis; and setting selection information of N pieces of demodulated data in a subsequent predetermined duration based on the determined priorities.

The selecting and outputting may further comprise setting a hit lock state or a hit unlock state of each of the N pieces of demodulated data based on whether continuous hits to the demodulation table occur in the predetermined duration, wherein the setting of the selection information comprises: updating the selection information based on the demodulated data of the highest priority if demodulated data of the highest priority is in the hit lock state in the predetermined duration; and not updating the selection information if the demodulated data of the highest priority is in the hit unlock state in the predetermined duration.

The data demodulation method may further comprise setting a frame sync lock state or a frame sync unlock state according to whether the frame sync signal is continuously detected, wherein if the frame sync lock state is set, the selecting and outputting is performed, and if the frame sync unlock state is set, the selecting and outputting is not performed.

According to another aspect of the present invention, there is provided a data demodulation apparatus comprising: a frame sync signal detection unit to detect a frame sync signal from input data; a data arrangement unit to arrange the input data on a predetermined unit basis based on a detected position of the frame sync signal; a shift register unit to output N pieces of predetermined unit data with respect to the predetermined unit data output from the data arrangement unit by shifting the predetermined unit data by a predetermined unit amount; a demodulation unit, comprising a demodulation table, to demodulate the N pieces of predetermined unit data using the demodulation table; and a demodulated data select and output unit to select and output one of the N pieces of demodulated data as demodulated data of the predetermined unit data.

The demodulated data select and output unit may comprise: a hit rate calculator to calculate a hit rate of the demodulation table in a predetermined duration for each of the N pieces of demodulated data output with respect to the predetermined unit data from the demodulation unit; a priority determiner to determine priorities of the N pieces of demodulated data based on the hit rate of the demodulation table calculated for each of the N pieces of demodulated data in the predetermined duration; and a selection information setting unit to set selection information of N pieces of demodulated data in a subsequent predetermined duration based on the determined priorities.

The demodulated data select and output unit may further comprise a hit lock/unlock state setting unit to set a hit lock state or a hit unlock state of each of the N pieces of demodulated data based on whether continuous hits to the demodulation table occur in the predetermined duration, wherein the selection information setting unit sets the selection information based on priorities determined by the priority determiner and the hit lock or unlock state of each of the N pieces of demodulated data provided by the hit lock/unlock state setting unit.

Additional and/or other aspects and advantages of the invention will be set forth in part in the description which follows and, in part, will be obvious from the description, or may be learned by practice of the invention.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 illustrates a Compact Disc (CD) frame format;

FIGS. 2A and 2B illustrate a Digital Versatile Disc (DVD) frame format;

FIG. 3A illustrates a normally detected frame sync signal;

FIGS. 3B and 3C illustrate incorrectly detected frame sync signals;

FIG. 4 is a block diagram of a data demodulation apparatus according to an embodiment of the present invention;

FIG. 5 is a block diagram of a shift register unit and a demodulation unit illustrated in FIG. 4, according to an embodiment of the present invention;

FIG. 6 is a block diagram of a demodulated data select and output unit illustrated in FIG. 4, according to an embodiment of the present invention;

FIG. 7 is a block diagram of the demodulated data select and output unit illustrated in FIG. 4, according to another embodiment of the present invention;

FIG. 8 is a flowchart of a data demodulation method according to an embodiment of the present invention;

FIG. 9 is a flowchart of a process of selecting and outputting demodulated data, which is illustrated in FIG. 8, according to an embodiment of the present invention;

FIG. 10 is a flowchart of a process of selecting and outputting demodulated data, which is illustrated in FIG. 8, according to another embodiment of the present invention; and

FIG. 11 is a flowchart of a data demodulation method according to another embodiment of the present invention.

### DETAILED DESCRIPTION OF THE EMBODIMENTS

Reference will now be made in detail to the present embodiments of the present invention, examples of which are illustrated in the accompanying drawings, wherein like reference numerals refer to the like elements throughout. The embodiments are described below in order to explain the present invention by referring to the figures.

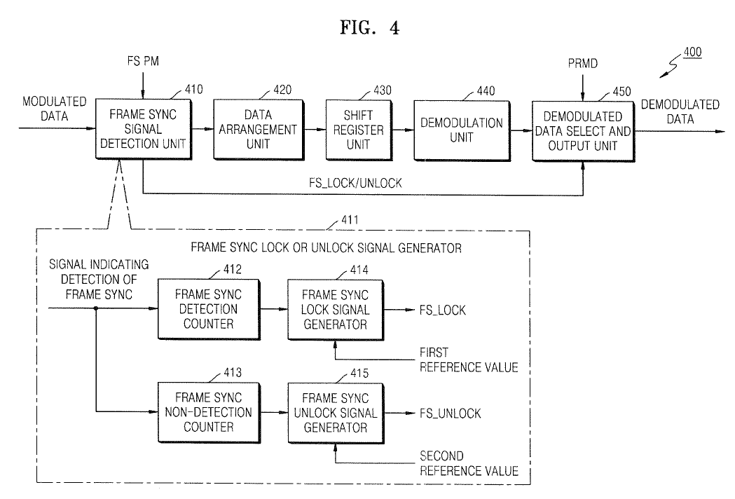

FIG. 4 is a block diagram of a data demodulation apparatus 400 according to an embodiment of the present invention. As shown in FIG. 4, the data demodulation apparatus 400 includes a frame sync signal detection unit 410, a data arrangement unit 420, a shift register unit 430, a demodulation unit 440, and a demodulated data select and output unit 450.

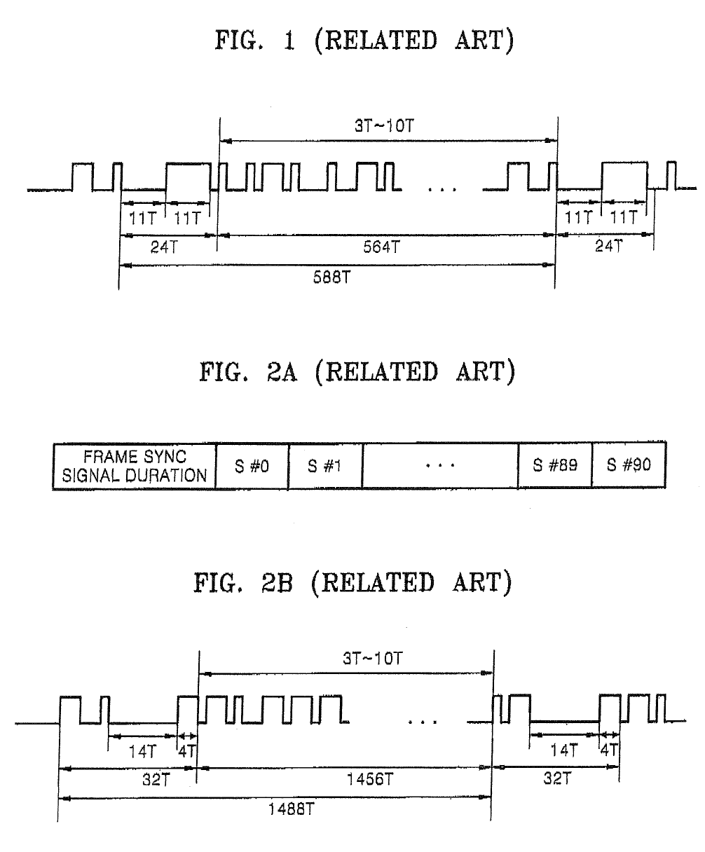

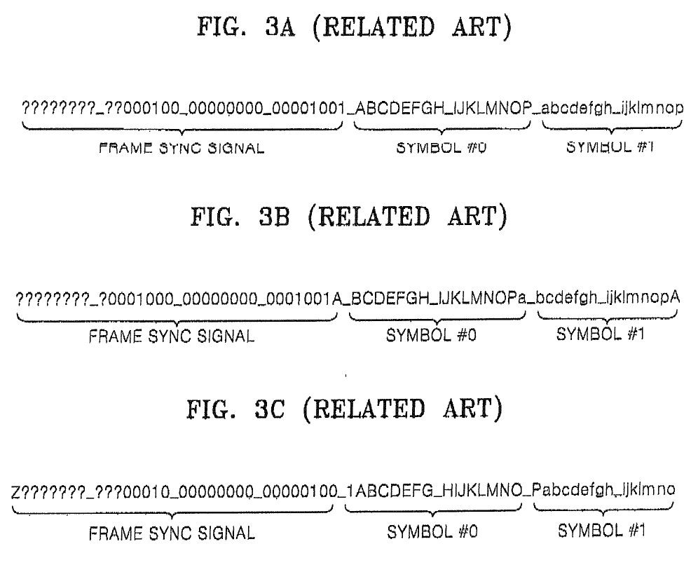

The frame sync signal detection unit 410 detects a frame sync signal from input data, which is modulated data, based on a Frame Sync Detection Mode (FSDM) and pre-set frame sync signal duration information. The FSDM may be one of a full pattern mode, a margin pattern mode, and a common pattern mode. The full pattern mode considers an overall frame sync signal duration when the frame sync signal is detected. The margin pattern mode considers a predetermined margin of the frame sync signal duration when the frame sync signal is detected. The common pattern mode detects the frame sync signal based on a duration that is distinguishable from other durations in the frame sync signal duration. For example, if the frame sync signal is similar to the frame sync signal that is illustrated in FIG. 1, in the common pattern mode, the frame sync signal is detected when a duration having 2 continuous 11Ts is detected. The FSDM is able to use one of the three modes and/or multiple modes in combination with each other. In addition, other modes are possible to achieve a similar effect.

The frame sync signal duration information is set in accordance with which device the data demodulation apparatus 400 is included in. For example, if the data demodulation apparatus 400 is included in a Compact Disc (CD) recording and reproducing device, the frame sync signal duration information is set as information on 24T, as illustrated in FIG. 1. If the data demodulation apparatus 400 is included in a Digital Versatile Disc (DVD) recording and reproducing device, the frame sync signal duration information is set as information on 32T, as illustrated in FIG. 2B.

The frame sync signal detection unit 410 may additionally generate a frame sync lock/frame sync unlock signal FS_LOCK/FS_UNLOCK. A frame sync lock state indicates that the frame sync signal is continuously detected, and a frame sync unlock state indicates that the frame sync signal is not continuously detected. Thus, if the frame sync signal detection unit 410 generates a frame sync lock/frame sync unlock signal FS_LOCK/FS_UNLOCK, the frame sync signal detection unit 410 may further include a frame sync lock or unlock signal generator 411, as illustrated in FIG. 4.

The frame sync lock or unlock signal generator 411 includes a frame sync detection counter 412, a frame sync non-detection counter 413, a frame sync lock signal generator 414, and a frame sync unlock signal generator 415. Here, it is understood that other embodiments for the frame sync lock or unlock signal generator are possible.

If a process including signal denoting frame sync detection indicates that the frame sync signal is detected on a frame basis from modulated data, the frame sync detection counter 412 increases a count value thereof, and the frame sync non-detection counter 413 resets a count value thereof. On the other hand, if a signal denoting frame sync detection indicates that the frame sync signal is not detected on a frame basis from modulated data, the frame sync non-detection counter 413 increases its count value, and the frame sync detection counter 412 resets its count value.

If the count value of the frame sync detection counter 412 is greater than a first reference value, the frame sync lock signal generator 414 determines that it is in the frame sync lock state and generates a frame sync lock signal to indicate that the frame sync signal is continuously detected. If the count value of the frame sync detection counter 412 is reset after the generating of the frame sync lock signal, the frame sync lock signal generator 414 does not generate the frame sync lock signal.

If the count value of the frame sync non-detection counter 413 is greater than a second reference value, the frame sync unlock signal generator 415 determines that it is in the frame sync unlock state and generates a frame sync unlock signal to indicate that the frame sync signal is not continuously detected. If the count value of the frame sync non-detection counter 413 is reset after generating the frame sync unlock signal, the frame sync unlock signal generator 415 does not generate the frame sync unlock signal. Here, it is understood that the first reference value and the second reference value may or may not be the same.

The data arrangement unit 420 arranges the input data (or modulated data) on a predetermined unit basis that is based on a detected position of the frame sync signal. The predetermined unit may be a byte unit or another measurable unit. For example, if the data demodulation apparatus 400 is included in a CD recording and reproducing device, the predetermined unit is 1 byte which is, itself, composed of 14 bits. If the data demodulation apparatus 400 is included in a DVD recording and reproducing device, the predetermined unit is 1 byte which is, itself, composed of 16 bits. If the data demodulation apparatus 400 is included in a HD-DVD or BD recording and reproducing device, the predetermined unit may be 1 byte, which is, itself, composed of 12 bits. The predetermined unit may also be defined symbolically. Accordingly, the data arrangement unit 420 outputs data of the predetermined unit.

The shift register unit 430 outputs N pieces of predetermined unit data with respect to the predetermined unit data output from the data arrangement unit 420. The shift register unit 430 does so by shifting the predetermined unit data by a predetermined unit amount. The predetermined unit amount for the shifting may be at least 1 bit or another measurable amount. Hereinafter, it is assumed that the predetermined unit amount for the shifting is 1 bit.

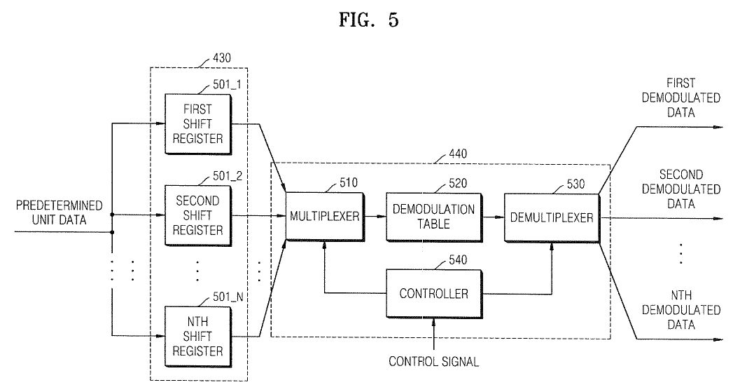

That is, as illustrated in FIG. 5, which is a block diagram of the shift register unit 430 and the demodulation unit 440 illustrated in FIG. 4, according to an embodiment of the present invention, the shift register unit 430 includes first through N^{th} shift registers 501_1 through 501_N. The first shift register 501_1 outputs the predetermined unit data without shifting. The second shift register 501_2 shifts the predetermined unit data by 1 bit and outputs the 1-bit-shifted predetermined unit data. The N^{th} shift register 501_N shifts the predetermined unit data by (N−1) bits and outputs the (N−1)-bit-shifted predetermined unit data, where N is equal to or less than the number of bits composing the predetermined unit. For example, if the predetermined unit is composed of 16 bits, N is equal to or less than 16.

Therefore, if N is 3, the shift register unit 430 outputs 3 pieces of predetermined unit data with respect to the predetermined unit data comprising one piece of non-shifted predetermined unit data, one piece of 1-bit-shifted predetermined unit data, and one piece of 2-bit-shifted predetermined unit data. Similarly, if N is 16, the N^{th} shift register 501_N outputs 15-bit-shifted predetermined unit data. Thus, the shift register unit 430 outputs 16 pieces of predetermined unit data with respect to input predetermined unit data. The 16 pieces of predetermined unit data comprise one piece of non-shifted predetermined unit data and 15 pieces of predetermined unit data that are obtained by shifting the predetermined unit data by 1 bit to 15 bits.

The demodulation unit 440 demodulates the N pieces of predetermined unit data output from the shift register unit 430. To do this, the demodulation unit 440 may be configured as illustrated in FIG. 5. That is, the demodulation unit 440 may include a multiplexer 510, a demodulation table 520, a demultiplexer 530, and a controller 540 although other configurations for the demodulation unit 440 are possible.

The multiplexer 510 sequentially selects the N pieces of predetermined unit data output from the shift register unit 430 and outputs the selected predetermined unit data to the demodulation table 520. The demodulation table 520 searches demodulation data corresponding to modulated data output from the multiplexer 510. If the corresponding demodulation data is found, the demodulation table 520 outputs the found demodulation data and flag information indicating that the corresponding demodulation data is found, as demodulated data.

If demodulation data that corresponds to modulated data output from the multiplexer 510 is not found, the demodulation table 520 outputs ‘0XFF’ to replace the demodulation data along with flag information that indicates that demodulation data is not found, as demodulated data. The value ‘0XFF’ may be replaced with another value. If the shift register unit 430 outputs N pieces of predetermined unit data, the demodulation table 520 outputs N pieces of demodulated data.

The demultiplexer 530 sequentially outputs the N pieces of demodulated data output from the demodulation table 520 to the demodulated data select and output unit 450 illustrated in FIG. 4. The controller 540 is enabled by an input control signal and thereby controls a selection operation of the multiplexer 510 and the demultiplexer 530. The control signal may be provided by a control unit (not shown) that controls an overall operation of a device including the data demodulation apparatus 400.

The demodulated data select and output unit 450 selects and outputs one of the N pieces of demodulated data as demodulated data of the predetermined unit data. That is, the demodulated data select and output unit 450 calculates a hit rate of the demodulation table 520 on a predetermined duration basis for each of the N pieces of demodulated data and updates or sets the selection information based on the calculated hit rates while selecting and outputting one of currently input N pieces of demodulated data using pre-set selection information. The pre-set selection information is set based on hit rates of the demodulation table 520 for N pieces of demodulated data in a previous predetermined duration. The selection information is set to a natural number from 1 to N. The predetermined duration may be set to a frame unit, a sector unit, or an Error Correction Code (ECC) block unit.

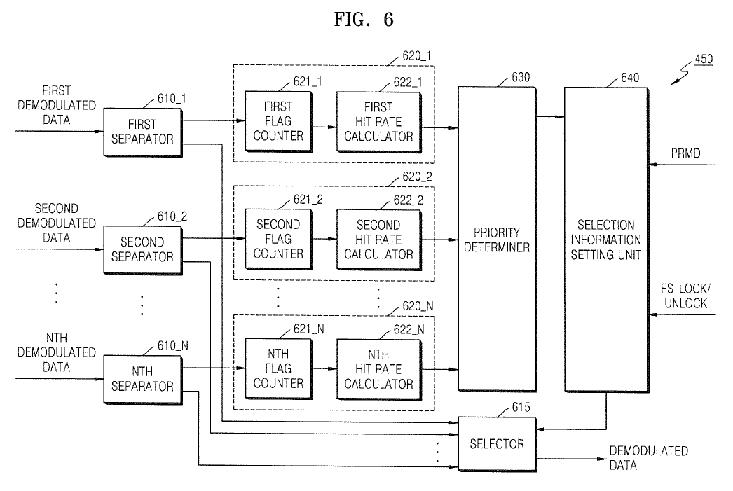

According to an embodiment of the invention, the demodulated data select and output unit 450 may be configured as illustrated in FIG. 6. As shown in FIG. 6, the demodulated data select and output unit 450 includes first through N^{th} separators 610_1 through 610_N, a selector 615, first through N^{th} hit rate calculation units 620_1 through 620_N, a priority determiner 630, and a selection information setting unit 640. It is understood that other configurations of the demodulated data select and output unit 450 are possible.

The first through N^{th} separators 610_1 through 610_N respectively separate demodulation data and flag information from input N pieces of demodulated data (first through N^{th} demodulated data), transmit the demodulation data to the selector 615, and transmit the flag information to the first through N^{th} hit rate calculation units 620_1 through 620_N.

The selector 615 selects one of the N pieces of demodulation data received from the first through N^{th} separators 610_1 through 610_N based on selection information that is output from the selection information setting unit 640. Further, the selector 615 outputs the selected demodulation data as demodulated data of the predetermined unit data. For example, if the selection information is “2”, the selector 615 outputs demodulation data received from the second separator 610_2, from among the demodulation data received from the first through N^{th} separators 610_1 through 610_N, as demodulated data of the predetermined unit data.

The first hit rate calculation unit 620_1 includes a first flag counter 621_1 and a first hit rate calculator 622_1. Every time input flag information indicates that corresponding demodulation data has been found from the demodulation table 520, the first flag counter 621_1 increases a count value thereof. For example, if flag information of “1” indicates that corresponding demodulation data has been founded from the demodulation table 520, the first flag counter 621_1 increases a count value thereof by 1 every time flag information of “1” is input.

The first hit rate calculator 622_1 calculates a hit rate of the demodulation table 520 for corresponding predetermined unit data in a predetermined duration based on the count value of the first flag counter 621_1. For example, if the predetermined duration is a frame unit, and if 1 frame is composed of 90 pieces of predetermined unit data (or symbol data) as illustrated in FIG. 2A, the first hit rate calculator 622_1 calculates a hit rate of the demodulation table 520 for the predetermined unit data based on how many of the 90 pieces of flag information are input as “1”. The predetermined unit data in the first hit rate calculation unit 620_1 is predetermined unit data that is output from the first shift register 501_1.

The second hit rate calculation unit 620_2 includes a second flag counter 621_2 and a second hit rate calculator 622_2 and operates similarly to the first hit rate calculation unit 620_1. The N^{th} hit rate calculation unit 620_N includes an N^{th} flag counter 621_N and an N^{th} hit rate calculator 622_N and operates similarly to the first hit rate calculation unit 620_1.

The priority determiner 630 determines priorities of the first through N^{th} demodulated data based on the hit rates output from the first through N^{th} hit rate calculation units 620_1 through 620_N. That is, the priority determiner 630 determines priorities of the first through N^{th} demodulated data in the order of a higher hit rate. For example, if a hit rate of the demodulation table 520 output from the second hit rate calculation unit 620_2 is the highest among the hit rates of the demodulation table 520 output from the first through N^{th} hit rate calculation units 620_1 through 620_N, the priority determiner 630 determines that the second demodulated data has the highest priority.

If a Priority Decision Mode (PRMD) is set as a mode in which the only factor that is considered is priority, the selection information setting unit 640 provides selection information for N pieces of demodulated data (first through N^{th} demodulated data) in a current predetermined duration to the selector 615 and sets selection information for N pieces of demodulated data in a subsequent predetermined duration based on the highest priority determined by the priority determiner 630. For example, if existing selection information is “1”, and if the priority determiner 630 determines that the second demodulated data has the highest priority, the selection information setting unit 640 updates or sets the selection information to “2”. However, if existing selection information is “1”, and if the priority determiner 630 determines that the first demodulated data has the highest priority, the selection information setting unit 640 maintains the selection information as is. The selection information may be defined in such a manner that identification information of demodulated data is used. That is, 1 through N can be used as the identification information of the demodulated data.

If the PRMD is set as a mode in which a frame sync lock/unlock signal is further considered, the selection information setting unit 640 sets selection information according to priority determined by the priority determiner 630 as described above when a frame sync lock signal is input. If a frame sync unlock signal is input, the selection information setting unit 640 may not operate.

That is, if the frame sync lock signal is input from the frame sync signal detection unit 410, the demodulated data select and output unit 450 may operate, and if the frame sync unlock signal is input from the frame sync signal detection unit 410, the demodulated data select and output unit 450 may not operate.

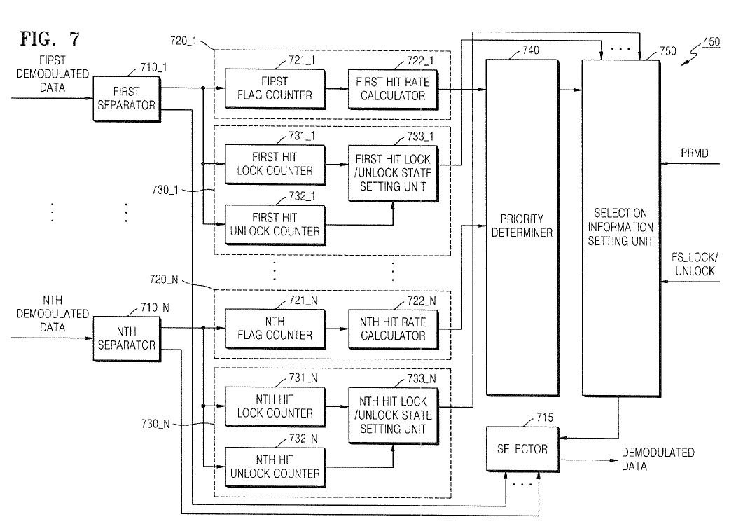

Meanwhile, the demodulated data select and output unit 450 may further consider whether continuous hits of the demodulation table 520 occur in a predetermined duration for first through N^{th} demodulated data. FIG. 7 is a block diagram of the demodulated data select and output unit 450 illustrated in FIG. 4, according to another embodiment of the present invention. Here, whether continuous hits of the demodulation table 520 occur is further considered in regard to the embodiment illustrated in FIG. 6.

As shown in FIG. 7, the demodulated data select and output unit 450 includes first through N^{th} separators 710_1 through 710_N, a selector 715, first through N^{th} hit rate calculation units 720_1 through 720_N, first through N^{th} hit lock/unlock state setting modules 730_1 through 730_N, a priority determiner 740, and a selection information setting unit 750.

The first through N^{th} separators 710_1 through 710_N, the selector 715, the first through N^{th} hit rate calculation units 720_1 through 720_N, and the priority determiner 740 illustrated in FIG. 7 are respectively configured and operate similarly to the first through N^{th} separators 610_1 through 610_N, the selector 615, the first through N^{th} hit rate calculation units 620_1 through 620_N, and the priority determiner 630 illustrated in FIG. 6.

The first hit lock/unlock state setting module 730_1 includes a first hit lock counter 731_1, a first hit unlock counter 732_1, and a first hit lock/unlock state setting unit 733_1. The first hit lock counter 731_1 increases a count value thereof every time corresponding predetermined unit data is determined to hit the demodulation table 520 based on flag information output from the first separator 710_1. Here, it is understood that the phenomenon of the predetermined unit data hitting the demodulation table 520 refers to the occurrence of demodulation data that corresponds to the predetermined unit data which is found from the demodulation table 520. Conversely, the phenomenon of the predetermined unit data not hitting the demodulation table 520 refers to the occurrence of the demodulation data that corresponds to the predetermined unit data which is not found from the demodulation table 520.

If predetermined unit data does not hit the demodulation table 520 after predetermined unit data continuously hits the demodulation table 520, the first hit lock counter 731_1 is reset. The first hit unlock counter 732_1 increases a count value thereof every time predetermined unit data does not hit the demodulation table 520. If predetermined unit data hits the demodulation table 520 after predetermined unit data does not continuously hit the demodulation table 520, the first hit unlock counter 732_1 is reset.

The first hit lock/unlock state setting unit 733_1 sets a hit lock/unlock state of predetermined unit data by monitoring the count value of the first hit lock counter 731_1 and the count value of the first hit unlock counter 732_1. That is, if the count value of the first hit lock counter 731_1 is greater than a third reference value, the first hit lock/unlock state setting unit 733_1 sets a hit lock state of predetermined unit data. If the count value of the first hit lock counter 731_1 is reset in the hit lock state, the first hit lock/unlock state setting unit 733_1 releases the hit lock state of predetermined unit data. If the count value of the first hit unlock counter 732_1 is greater than a fourth reference value, the first hit lock/unlock state setting unit 733_1 sets a hit unlock state of predetermined unit data. If the count value of the first hit unlock counter 732_1 is reset in the hit unlock state, the first hit lock/unlock state setting unit 733_1 releases the hit unlock state of predetermined unit data.

The N^{th} hit lock/unlock state setting module 730_N includes an N^{th} hit lock counter 731_N, an N^{th} hit unlock counter 732_N, and an N^{th} hit lock/unlock state setting unit 733_N and operates similarly to the first hit lock/unlock state setting module 730_1.

If the PRMD is set as a mode in which selection information is set using only priority information, the selection information setting unit 750 sets selection information based on priority information that is output from the priority determiner 740. However, if the PRMD is set as a mode in which a frame sync lock/unlock state is further considered, the selection information setting unit 750 sets selection information that is based on the priority information when a frame sync lock signal is input.

If the PRMD is set as a mode in which all of a frame sync lock/unlock state and a hit lock/unlock state are considered, the selection information setting unit 750 updates or sets selection information when a frame sync lock signal is input and demodulated data having the highest priority is set in the hit lock state.

If a frame sync lock signal is input and demodulated data having the highest priority is set in the hit unlock state, the selection information setting unit 750 maintains previously set selection information without an updating process or a setting of the selection information.

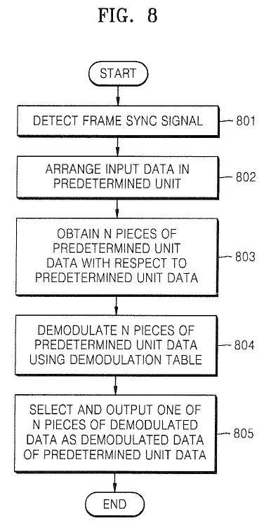

FIG. 8 is a flowchart of a data demodulation method according to an embodiment of the present invention. As shown in FIG. 8, a frame sync signal is detected from input data in operation 801 as in the frame sync signal detection unit 410 illustrated in FIG. 4.

The input data is arranged on a predetermined unit basis based on a detected position of the frame sync signal in operation 802 as described above in the description of the data arrangement unit 420. N pieces of predetermined unit data with respect to the predetermined unit data are obtained by shifting the predetermined unit data by a predetermined unit amount in operation 803 as described above in the description of the shift register unit 430. The predetermined unit shifting amount may be 1 bit.

The N pieces of predetermined unit data are demodulated using the demodulation table 520 in operation 804 as described above in the description of the demodulation unit 440. One of the N pieces of demodulated data is selected and output as demodulated data of the predetermined unit data in operation 805. That is, one of N pieces of demodulated data in a current predetermined duration is selected and output using pre-set selection information based on hit rates of the demodulation table 520 for N pieces of demodulated data in a previous predetermined duration. The previous or current predetermined duration may be set as a frame unit, a sector unit, or an ECC block unit.

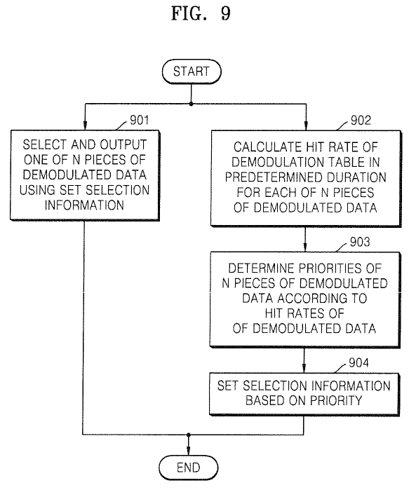

Operation 805, illustrated in FIG. 8, may be illustrated as shown in FIG. 9, which is a flowchart of a process of selecting and outputting the demodulated data of the predetermined unit data, according to an embodiment of the present invention. As shown in FIG. 9, while selecting and outputting one of N pieces of demodulated data using pre-set selection information in operation 901, a hit rate of the demodulation table 520 is calculated for each of the N pieces of demodulated data in a current predetermined duration in operation 902. The hit rates of the demodulation table 520 are calculated as in the first through N^{th} hit rate calculation units 620_1 through 620_N illustrated in FIG. 6.

Priorities of the N pieces of demodulated data are determined according to the calculated hit rates of the demodulation table 520 in operation 903. The priorities are determined as described above in the description of the priority determiner 630 illustrated in FIG. 6. Selection information is set based on the priorities in operation 904 as described above in the description of the selection information setting unit 640 illustrated in FIG. 6. That is, in the selecting and outputting of the demodulated data of the predetermined unit data, selection information is selected based on demodulation data having the highest priority.

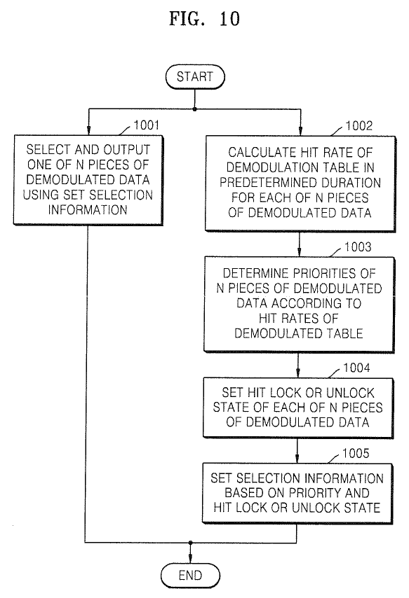

Meanwhile, operation 805, which is illustrated in FIG. 8, can be illustrated as shown in FIG. 10. FIG. 10 is a flowchart of the process of selecting and outputting the demodulated data of the predetermined unit data, according to another embodiment of the present invention. As shown in FIG. 10, while selecting and outputting one of N pieces of demodulated data using pre-set selection information in operation 1001, a hit rate of the demodulation table 520 is calculated for each of the N pieces of demodulated data in operation 1002 as described above in the description of the first through N^{th} hit rate calculation units 720_1 through 720_N illustrated in FIG. 7.

Priorities of the N pieces of demodulated data are determined according to the calculated hit rates of the demodulation table 520 in operation 1003. The priorities are determined as described above in the description of the priority determiner 740 illustrated in FIG. 7.

A hit lock or unlock state of each of the N pieces of demodulated data is set in operation 1004 based on whether continuous hits of the demodulation table 520 occur in the predetermined duration, as described above in the description of the first through N^{th} hit lock/unlock state setting modules 730_1 through 730_N illustrated in FIG. 7.

Selection information is set in operation 1005 based on the priorities determined in operation 1003 and the hit lock or unlock state set in operation 1004. That is, if demodulation data having the highest priority in the predetermined duration is in the hit lock state, the selection information is updated or set based on the demodulation data having the highest priority. If demodulation data having the highest priority in the predetermined duration is in the hit unlock state, the selection information is not updated or set. In this case, if identification information (one of 1 through N) of the demodulation data having the highest priority is the same as pre-set selection information, the selection information is not updated or set. That is, if pre-set selection information is “2”, and if demodulation data having the highest priority is “second demodulated data”, selection information to be set is “2”, and therefore, the selection information is not updated or set.

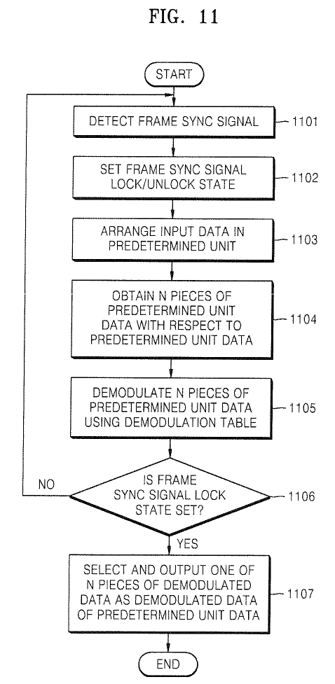

FIG. 11 is a flowchart of a data demodulation method, according to another embodiment of the present invention, in which a frame sync signal lock/unlock state is further considered in regard to the embodiment illustrated in FIG. 8. Thus, operations 1101, 1103, 1104, 1105, and 1107 of FIG. 11 are similar to operations 801 through to 805 illustrated in FIG. 8, respectively.

In operation 1102, a frame sync signal lock or unlock state is set as described above in the description in the frame sync signal detection unit 410 illustrated in FIG. 4.

If the frame sync signal lock state is determined to have been set in operation 1106, one of N pieces of demodulated data is selected and output as demodulated data of the predetermined unit data in operation 1107. If the frame sync signal lock state is determined to not have been set in operation 1106, demodulated data is not selected and output, and the process proceeds to operation 1101 in order to detect a frame sync signal.

The invention may also be embodied as computer readable codes on a computer readable recording medium. The computer readable recording medium is any data storage device that stores data which may be thereafter read by a computer system. Examples of the computer readable recording medium include read-only memory (ROM), random-access memory (RAM), CD-ROMs, magnetic tapes, floppy disks, optical data storage devices, and information transmitted in various forms over the wireless networks and the internet. The computer readable recording medium may also be distributed over network coupled computer systems so that the computer readable code is stored and executed in a distributed fashion.

As is described above, according to aspects of the present invention, when data is demodulated using a frame sync signal, by obtaining a plurality of pieces of predetermined unit data by shifting predetermined unit data (e.g., symbol data) by a predetermined unit amount and selecting demodulated data of the predetermined unit data based on hit rates of a demodulation table in a previous predetermined duration, a decrease in a data demodulation rate due to demodulation of data based on a wrongly detected frame sync signal is preventable.

Although a few embodiments of the present invention have been shown and described, it would be appreciated by those skilled in the art that changes may be made in these embodiments without departing from the principles and spirit of the invention, the scope of which is defined in the claims and their equivalents.

What is claimed is:

1. A data demodulation method comprising:
detecting a frame sync signal from input data;
arranging the input data on a predetermined unit basis that is based on a detected position of the frame sync signal;
obtaining N pieces of predetermined unit data with respect to the predetermined unit data by shifting the predetermined unit data by a predetermined unit amount;
demodulating the N pieces of predetermined unit data using a demodulation table; and
selecting and outputting one of the N pieces of demodulated data as demodulated data of the predetermined unit data.

2. The data demodulation method of claim 1, wherein the selecting and outputting comprises selecting one of the N pieces of demodulated data in a current predetermined duration using selection information that is set based on hit rates of the demodulation table for N pieces of demodulated data in a previous predetermined duration.

3. The data demodulation method of claim 2, wherein each of the previous predetermined duration and the current predetermined duration is set as a frame unit, a sector unit, or an Error Correction Code (ECC) block unit.

4. The data demodulation method of claim 2, wherein the selecting and outputting comprises:
calculating a hit rate of the demodulation table on a predetermined duration basis for each of the N pieces of demodulated data;
determining priorities of the N pieces of demodulated data based on the hit rate of the demodulation table calculated for each of the N pieces of demodulated data on the predetermined duration basis; and
setting selection information of N pieces of demodulated data in a subsequent predetermined duration based on the determined priorities.

5. The data demodulation method of claim 4, wherein the determining of the priorities comprises determining demodulated data having a highest hit rate of the demodulation table in the predetermined duration as demodulated data having the highest priority, and wherein the setting of the selection information comprises setting the selection information based on the demodulated data having the highest priority.

6. The data demodulation method of claim 5, wherein the selecting and outputting further comprises setting a hit lock state or a hit unlock state of each of the N pieces of demodulated data based on whether continuous hits to the demodulation table occur in the predetermined duration.

7. The data demodulation method of claim 6, wherein the setting of the selection information comprises:
updating the selection information based on the demodulated data of the highest priority if demodulated data of the highest priority is in the hit lock state in the predetermined duration; and
not updating the selection information if the demodulated data of the highest priority is in the hit unlock state in the predetermined duration.

8. The data demodulation method of claim 7, further comprising setting a frame sync lock state or a frame sync unlock state according to whether the frame sync signal is continuously detected, wherein, if the frame sync lock state is set, the selecting and outputting is performed, and, if the frame sync unlock state is set, the selecting and outputting is not performed.

9. The data demodulation method of claim 1, further comprising setting a frame sync lock state or a frame sync unlock state according to whether the frame sync signal is continuously detected, wherein, if the frame sync lock state is set, the selecting and outputting is performed, and, if the frame sync unlock state is set, the selecting and outputting is not performed.

10. A data demodulation apparatus comprising:
a frame sync signal detection unit to detect a frame sync signal from input data;
a data arrangement unit to arrange the input data on a predetermined unit basis based on a detected position of the frame sync signal;
a shift register unit to output N pieces of predetermined unit data with respect to the predetermined unit data output from the data arrangement unit by shifting the predetermined unit data by a predetermined unit amount;
a demodulation unit, including a demodulation table, to demodulate the N pieces of predetermined unit data using the demodulation table; and
a demodulated data select and output unit to select and output one of the N pieces of demodulated data as demodulated data of the predetermined unit data.

11. The data demodulation apparatus of claim 10, wherein the demodulated data select and output unit selects one of the N pieces of demodulated data in a current predetermined duration using selection information set based on hit rates of the demodulation table for N pieces of demodulated data in a previous predetermined duration.

12. The data demodulation apparatus of claim 11, wherein each of the previous predetermined duration and the current predetermined duration is set as a frame unit, a sector unit, or an Error Correction Code (ECC) block unit.

13. The data demodulation apparatus of claim 10, wherein the shift register unit comprises N shift registers, and wherein the demodulation unit comprises:
a multiplexer to sequentially select predetermined unit data output from the N shift registers and to output the selected predetermined unit data to the demodulation table;
a demultiplexer to sequentially output demodulated data output from the demodulation table to the demodulated data select and output unit; and
a controller to control a selection operation of the multiplexer and the demultiplexer.

14. The data demodulation apparatus of claim 10, wherein the demodulated data select and output unit comprises:
a hit rate calculation module to calculate a hit rate of the demodulation table in a predetermined duration for each of the N pieces of demodulated data output from the demodulation unit with respect to the predetermined unit data;
a priority determiner to determine priorities of the N pieces of demodulated data based on the hit rate of the demodulation table calculated for each of the N pieces of demodulated data in the predetermined duration; and
a selection information setting unit to set selection information of N pieces of demodulated data in a subsequent predetermined duration based on the determined priorities.

15. The data demodulation apparatus of claim 14, wherein the priority determiner determines priorities of the N pieces of demodulated data in the order of a higher hit rate of the demodulation table in the predetermined duration, and wherein the selection information setting unit sets the selection information based on the piece of the demodulated data having the highest priority.

16. The data demodulation apparatus of claim 15, wherein the priority determiner determines which piece of the demodulated data has the highest priority.

17. The data demodulation apparatus of claim 16, wherein the demodulated data select and output unit further comprises a hit lock/unlock state setting unit to set a hit lock state or a hit unlock state of each of the N pieces of demodulated data based on whether continuous hits to the demodulation table occur in the predetermined duration, and wherein the selection information setting unit sets the selection information based on the priorities determined by the priority determiner and the hit lock state or hit unlock state of each of the N pieces of demodulated data.

18. The data demodulation apparatus of claim 17, wherein the hit lock/unlock state setting unit provides the hit lock state or hit unlock state of each of the N pieces of demodulated data.

19. The data demodulation apparatus of claim 18, wherein the selection information setting unit updates or sets the selection information based on the piece of the demodulated data having the highest priority if the demodulated data having the highest priority is in the hit lock state in the predetermined duration, and does not update or set the selection information if the piece of the demodulated data having the highest priority is in the hit unlock state in the predetermined duration.

20. The data demodulation apparatus of claim 19, wherein, if a frame sync lock signal that indicates that a frame sync signal is continuously detected is received from the frame sync signal detection unit, the demodulated data select and output unit operates, and, if a frame sync unlock signal that indicates that a frame sync signal is not continuously detected is received from the frame sync signal detection unit, the demodulated data select and output unit does not operate.

21. The data demodulation apparatus of claim 10, wherein, if a frame sync lock signal that indicates that a frame sync signal is continuously detected is received from the frame sync signal detection unit, the demodulated data select and output unit operates, and, if a frame sync unlock signal that indicates that a frame sync signal is not continuously detected is received from the frame sync signal detection unit, the demodulated data select and output unit does not operate.

22. A data demodulation apparatus comprising:
a detection unit to detect a frame sync signal from input data read from the optical storage medium;
an arrangement unit to arrange the input data on a predetermined unit basis based on a position of the frame sync signal;
a shift register to output N pieces of the predetermined unit data, each of the N pieces of the predetermined unit data having been shifted by respective N−1 predetermined unit amounts;
a demodulation unit, including a demodulation table, to demodulate the N pieces of predetermined unit data based on the demodulation table to determine a characteristic of each of the N pieces of the predetermined unit data; and
a select and output unit to select and output one of the N pieces of demodulated data based on the characteristic.

23. The data demodulation apparatus according to claim 22, wherein the characteristic comprises a relative priority of each of the N pieces of the predetermined unit data.

24. The data demodulation apparatus according to claim 23, wherein the relative priority is determined based on the frequency of the predetermined unit data hitting the demodulation table.

25. The data demodulation apparatus according to claim 23, wherein the characteristic further comprises a hit lock or hit unlock state of each of the N pieces of predetermined unit data.
